(19) United States
(12) Patent Application Publication
(10) Pub. No.: US 2025/0216318 A1
(43) Pub. Date: Jul. 3, 2025

(54) PLASMA-RESISTANT O-RING EVALUATION UNIT AND DEVICE

(71) Applicant: SEMES CO., LTD., Cheonan-si (KR)

(72) Inventors: Chang Eon PARK, Cheonan-si (KR); Yong Seok SEO, Cheonan-si (KR); Jae Hyeon LEE, Cheonan-si (KR)

(73) Assignee: SEMES CO., LTD., Cheonan-si (KR)

(21) Appl. No.: 19/004,248

(22) Filed: Dec. 28, 2024

(30) Foreign Application Priority Data
Dec. 28, 2023 (KR) 10-2023-0195681

(51) Int. Cl. G01N 17/00; G01M 3/04

(52) U.S. Cl. CPC G01N 17/00; G01M 3/04

(57) ABSTRACT

Disclosed are a plasma-resistant O-ring evaluation unit and device, and more particularly technology capable of mounting a plurality of various O-rings in an O-ring evaluation unit and selectively exposing the O-rings to plasma in a plasma environment to quickly and accurately determine the plasma resistance characteristics of the plurality of various O-rings.

### CROSS-REFERENCE TO THE RELATED APPLICATION

The present application claims priority to and the benefit of Korean Patent Application No. 10-2023-0195681, filed on December 2023, in the Korean Intellectual Property Office, the entire disclosure of which is incorporated herein by reference.

### BACKGROUND

### 1. Field

Embodiments of the present disclosure relate to a plasma-resistant O-ring evaluation unit and device, and more particularly to technology capable of mounting a plurality of various O-rings in an O-ring evaluation unit and selectively exposing the O-rings to plasma in a plasma environment to quickly and accurately determine the plasma resistance characteristics of the plurality of various O-rings.

### 2. Description of the Related Art

A plasma substrate processing apparatus has a plurality of components coupled to constitute a single apparatus. In the substrate processing apparatus, an O-ring is mounted to prevent an inner component from being exposed to plasma gas such that sealing is performed to prevent penetration of the plasma gas.

If the O-ring that performs sealing against the plasma gas does not have appropriate plasma resistance characteristics, the plasma gas penetrates into the inner component of the substrate processing apparatus, causing damage to the inner component, which results in a short maintenance cycle of the substrate processing apparatus and, furthermore, a decrease in process yield.

Therefore, it is necessary to apply an O-ring having appropriate plasma resistance characteristics for each mounting site.

Conventionally, in order to evaluate the plasma resistance characteristics of an O-ring to be evaluated, the O-ring is directly exposed to a plasma environment to evaluate the plasma resistance characteristics of the O-ring.

However, when the O-ring is directly exposed to the plasma environment for evaluation, which is different from the environment in which the O-ring is mounted in an actual substrate processing apparatus, there is a problem of obtaining results different from the plasma resistance characteristics of the O-ring in an actual process environment.

Alternatively, the O-ring to be evaluated is mounted in the substrate processing apparatus and the actual substrate processing apparatus is operated to indirectly expose the O-ring to the plasma environment to evaluate the plasma resistance characteristics of the O-ring.

This evaluation method reflects the actual process environment and thus may accurately evaluate the plasma resistance characteristics of the O-ring to be evaluated, but the evaluation time for evaluating various O-rings is long accordingly.

### SUMMARY

The present disclosure has been made in view of the above problems, and it is an object of the present disclosure to provide a scheme capable of quickly and accurately evaluating the plasma resistance characteristics of a plurality of various O-rings through a single plasma resistance evaluation process.

In particular, when the O-ring is directly exposed to the plasma environment for evaluation, which is different from the environment in which the O-ring is mounted in an actual substrate processing apparatus, there is a problem of obtaining results different from the plasma resistance characteristics of the O-ring in an actual process environment. It is another object of the present disclosure to solve the above problem.

In addition, when an O-ring to be evaluated is mounted in a substrate processing apparatus and an actual substrate processing apparatus is operated to indirectly expose the O-ring to the plasma environment to evaluate the plasma resistance characteristics of the O-ring, the evaluation time for evaluating various O-rings is long accordingly. It is a further object of the present disclosure to solve the above problem.

The objects of the present disclosure are not limited to the aforementioned objects, and other unmentioned objects and advantages will be clearly understood by a person having ordinary skill in the art to which the present disclosure pertains based on the following description.

In accordance with an aspect of the present disclosure, the above and other objects can be accomplished by the provision of a plasma-resistant O-ring evaluation unit including a body provided in an upper surface thereof with an O-ring mounting groove corresponding in shape to an O-ring to be evaluated and a cover mounted to the top of the body, wherein a plasma gas penetration path configured to allow plasma gas to penetrate into the mounted O-ring to be evaluated therethrough is formed by coupling between the body and the cover.

The cover may be provided with a cover interior penetration through-hole configured to support inner penetration of plasma gas, and the plasma gas penetration path may include an inner penetration path formed by a gap between inner contact surfaces of the body and the cover by coupling between the body and the cover, the inner penetration path being configured to allow plasma gas introduced through the cover interior penetration through-hole to penetrate through the gap between the inner contact surfaces, and an outer penetration path formed by a gap between outer contact surfaces of the body and the cover by coupling between the body and the cover, the outer penetration path being configured to allow plasma gas from outside to penetrate through the gap between the outer contact surfaces.

Furthermore, the cover may be provided in the center thereof with a cover interior penetration through-hole configured to support inner penetration of plasma gas, and the body may include an inner penetration O-ring mounting groove provided in a central region thereof, a sealing O-ring mounting groove provided in a middle region thereof, and an outer penetration O-ring mounting groove provided in an outer region thereof.

An O-ring mounted in the sealing O-ring mounting groove may block the flow of plasma gas penetrated through the inner penetration path and the outer penetration path.

In an example, the body may be provided with a body interior penetration through-hole connected to the cover interior penetration through-hole.

Furthermore, the cover may be provided with a fastener through-hole for coupling to the body, the body may be provided with a fastener coupling recess corresponding to the fastener through-hole of the cover, and the plasma-resistant O-ring evaluation unit may further include a coupling fastener inserted through the fastener through-hole of the cover and fastened to the fastener coupling recess of the body.

The plasma-resistant O-ring evaluation unit may further include a gap adjustment ring fastened to the coupling fastener between the cover and the body.

In an example, the gap adjustment ring may be changed in number to adjust the gap between the inner contact surfaces and the gap between the outer contact surfaces.

In an example, the gap adjustment ring may be changed in thickness to adjust the gap between the inner contact surfaces and the gap between the outer contact surfaces.

Furthermore, the body may include an upper body, to the top of which the cover is mounted, and a lower body, to the top of which the upper body is mounted.

Alternatively, the body may include a plurality of bodies sequentially mounted to a bottom of the cover.

The upper body may be provided with a body interior penetration through-hole connected to the cover interior penetration through-hole.

In an example, each of the cover and the upper body may be provided with a fastener through-hole, the lower body may be provided with a fastener coupling recess corresponding to the fastener through-hole, and the plasma-resistant O-ring evaluation unit may further include a coupling fastener inserted through the fastener through-hole and fastened to the fastener coupling recess.

In an example, the plasma-resistant O-ring evaluation unit may further include a gap adjustment ring selectively fastened to the coupling fastener between the cover and the upper body or between the upper body and the lower body.

In an example, the cover may be provided with a fastener through-hole for coupling to the upper body, the upper body may be provided with a fastener coupling recess corresponding to the fastener through-hole of the cover and a fastener through-hole for coupling to the lower body, and the plasma-resistant O-ring evaluation unit may further include a first coupling fastener inserted through the fastener through-hole of the cover and fastened to the fastener coupling recess of the upper body and a second coupling fastener inserted through the fastener through-hole of the upper body and fastened to a fastener coupling recess of the lower body.

In an example, the plasma-resistant O-ring evaluation unit may further include a gap adjustment ring fastened to the first coupling fastener between the cover and the upper body or fastened to the second coupling fastener between the upper body and the lower body.

In accordance with another aspect of the present disclosure, there is provided a plasma-resistant O-ring evaluation device including a chamber having an O-ring evaluation space configured to provide a plasma environment, the plasma-resistant O-ring evaluation unit disposed in the O-ring evaluation space; and a plasma environment creation unit configured to create the plasma environment in the O-ring evaluation space of the chamber.

In an example, the plasma environment creation unit may create the plasma environment in the O-ring evaluation space of the chamber in a CCP mode.

In an example, the plasma environment creation unit may create the plasma environment in the O-ring evaluation space of the chamber in an ICP mode.

In accordance with a further aspect of the present disclosure, there is provided a plasma-resistant O-ring evaluation device including a cover provided in the center thereof with a cover interior penetration through-hole configured to support inner penetration of plasma gas, the cover being mounted to the top of a body, a plurality of bodies sequentially mounted to the bottom of the cover, each of the bodies being provided with a body interior penetration through-hole connected to the cover interior penetration through-hole, each of the bodies including an inner penetration O-ring mounting groove provided in a central region of an upper surface thereof, a sealing O-ring mounting groove provided in a middle region of the upper surface thereof, and an outer penetration O-ring mounting groove provided in an outer region of the upper surface thereof so as to correspond in shape to different O-rings to be evaluated, a plasma-resistant O-ring evaluation unit including a plasma gas penetration path, the plasma gas penetration path including an inner penetration path formed by a gap between inner contact surfaces of the body and the cover and between inner contact surfaces of the bodies by coupling between the body and the cover and coupling between the covers, the inner penetration path being configured to allow plasma gas introduced through the cover interior penetration through-hole or the body interior penetration through-hole to penetrate through the gap between the inner contact surfaces, and an outer penetration path formed by a gap between outer contact surfaces of the body and the cover and between outer contact surfaces of the bodies, the outer penetration path being configured to allow plasma gas from outside to penetrate through the gap between the outer contact surfaces, a chamber having an O-ring evaluation space configured to provide a plasma environment, the plasma-resistant O-ring evaluation unit being disposed in the O-ring evaluation space, and a plasma environment creation unit configured to create the plasma environment in the O-ring evaluation space of the chamber.

### BRIEF DESCRIPTION OF THE DRAWINGS

The accompanying drawings, which are incorporated in this specification, illustrate exemplary embodiments and serve to further illustrate the technical ideas of the present disclosure in conjunction with the detailed description of exemplary embodiments that follows, and the present disclosure is not to be construed as limited to what is shown in such drawings. In the drawings:

FIG. 1A and 1B are a view showing an embodiment of a plasma-resistant O-ring evaluation unit according to the present disclosure;

FIG. 2 is a separated sectional view showing the embodiment of the plasma-resistant O-ring evaluation unit according to the present disclosure;

FIG. 3 is a sectional view showing the embodiment of the plasma-resistant O-ring evaluation unit according to the present disclosure;

FIGS. 4A, 4B and 5 are views showing an embodiment of adjusting the gap of a plasma gas penetration path in the plasma-resistant O-ring evaluation unit according to the present disclosure;

FIG. 6 is a view showing an embodiment of a plasma-resistant O-ring evaluation device according to the present disclosure;

FIGS. 7A, 7B, 8, and 9 are views showing another embodiment of the plasma-resistant O-ring evaluation unit according to the present disclosure;

FIG. 10 is a view showing another embodiment of adjusting the gap of the plasma gas penetration path in the plasma-resistant O-ring evaluation unit according to the present disclosure; and

FIGS. 11 and 12 are views showing a further embodiment of the plasma-resistant O-ring evaluation unit according to the present disclosure.

### DETAILED DESCRIPTION OF EXEMPLARY EMBODIMENTS

Hereinafter, preferred embodiments of the present disclosure will be described in detail with reference to the accompanying drawings, but the present disclosure is not limited or restricted by the embodiments.

In order to describe the present disclosure, operational advantages of the present disclosure, and objects achieved by practicing the present disclosure, preferred embodiments of the present disclosure will hereinafter be illustrated and a description will be given with reference thereto.

First, it should be noted that the terminology used in the present application is used only to describe specific embodiments and is not intended to limit the present disclosure, and singular forms are intended to include plural forms unless mentioned otherwise. It should also be understood that in the present application, the terms “including” or “having” and the like are intended to designate the presence of the features, numbers, steps, operations, components, parts, or combinations thereof described in the specification, and not to preclude the possibility of the presence or addition of one or more other features, numbers, steps, operations, components, parts, or combinations thereof.

In describing the present disclosure, a detailed description of known configurations or functions incorporated herein will be omitted when the same may obscure the subject matter of the present disclosure.

The present disclosure proposes a technology capable of mounting a plurality of various O-rings in an O-ring evaluation unit and selectively exposing the O-rings to plasma in a plasma environment to quickly and accurately determine the plasma resistance characteristics of the plurality of various O-rings.

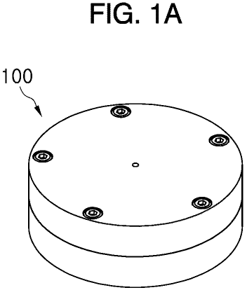

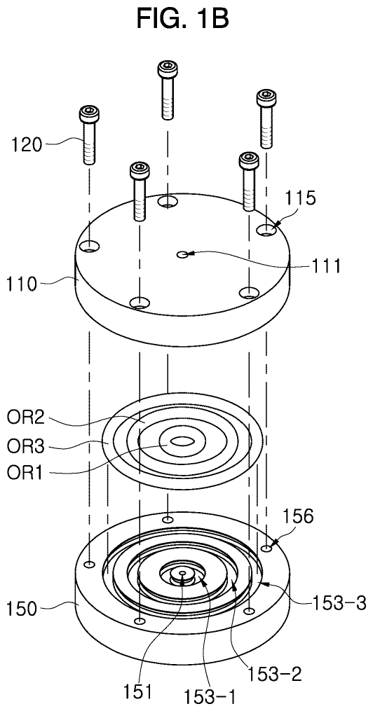

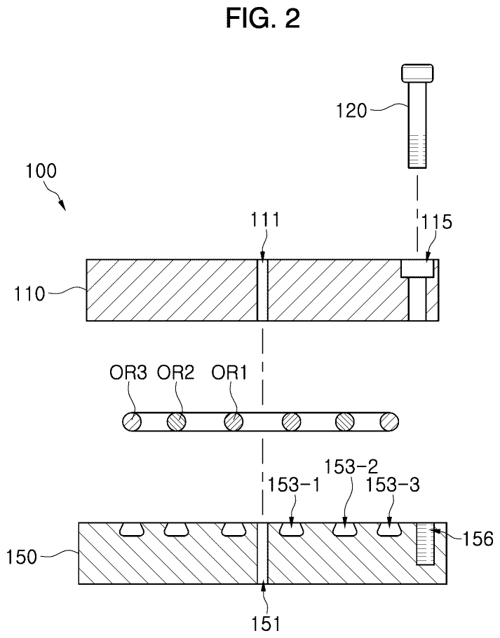

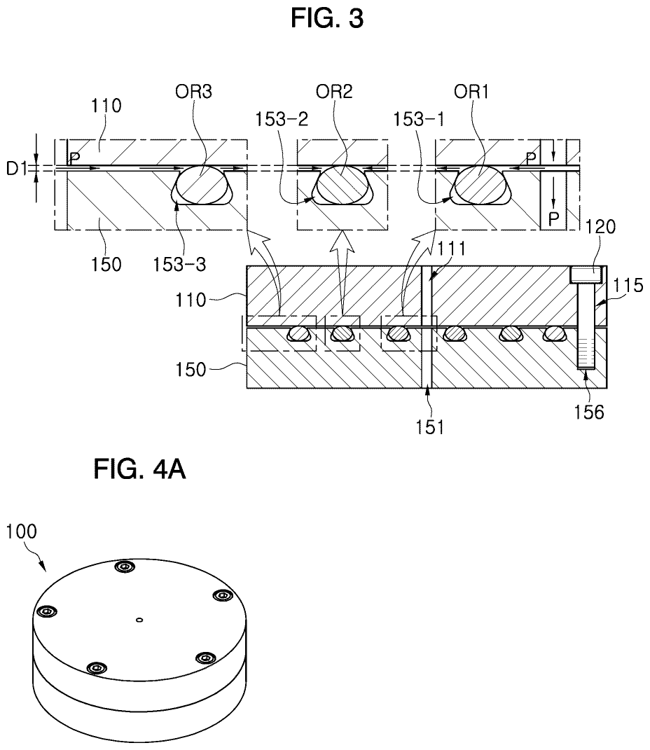

FIG. 1A and 1B are a view showing an embodiment of a plasma-resistant O-ring evaluation unit according to the present disclosure, FIG. 2 is a separated sectional view showing the embodiment of the plasma-resistant O-ring evaluation unit according to the present disclosure, and FIG. 3 is a sectional view showing the embodiment of the plasma-resistant O-ring evaluation unit according to the present disclosure.

The plasma-resistant O-ring evaluation unit 100 may include a cover 110, a body 150, and a coupling fastener 120.

Each of the cover 110, the body 150, and the coupling fastener 120 may be made of a material resistant to plasma gas.

The body 150 may be provided in an upper surface thereof with a plurality of O-ring mounting grooves 153-1, 153-2, and 153-3 corresponding in shape to the O-rings OR1, OR2, and OR3 to be evaluated.

The O-ring mounting grooves 153-1, 153-2, and 153-3 may be formed in the upper surface of the body 150 in a state of being depressed into the body 150 so as to correspond in shape to the O-rings OR1, OR2, and OR3 to be evaluated. In one example, each of the O-ring mounting grooves 153-1, 153-2, and 153-3 may be formed such that the entirety or at least a part of a corresponding one of the O-rings OR1, OR2, and OR3 to be evaluated is inserted thereinto.

An inner penetration O-ring mounting groove 153-1 may be provided in a central region of the body 150, a sealing O-ring mounting groove 153-2 may be provided in a middle region of the body 150, and an outer penetration O-ring mounting groove 153-3 may be provided in an outer region of the body 150 so as to correspond to the diameters of the O-rings OR1, OR2, and OR3 to be evaluated based on the center point thereof.

The O-rings OR1, OR2, and OR3 to be evaluated may be inserted into and mounted in the O-ring mounting grooves 153-1, 153-2, and 153-3 of the body 150, respectively. The plurality of the O-rings OR1, OR2, and OR3 to be evaluated may be targets for evaluation of plasma resistance characteristics, and O-rings having different sizes and made of different materials may be selected. Alternatively, O-rings having different sizes but made of the same material may be selected.

The cover 110 may be mounted to the top of the body 150. The cover 110 may press the O-rings OR1, OR2, and OR3 to be evaluated against the top of the body 150. The cover 110 may be provided in the center thereof with a cover interior penetration through-hole 111 configured to allow plasma gas to penetrate into the cover 110. The cover interior penetration through-hole 111 may be formed as a hole formed through the cover 110 from the top to the bottom.

The body 150 may be provided with a body interior penetration through-hole 151 connected to the cover interior penetration through-hole 111. The body interior penetration through-hole 151 may be optionally provided in the body 150.

The cover 110 may be provided in an outer region thereof with a fastener through-hole 115 for engagement with the body 150 formed along the circumference thereof, and the body 150 may be provided with a fastener coupling recess 156 corresponding to the fastener through-hole 115 of the cover 110.

The coupling fastener 120 may be inserted through the fastener through-hole 115 of the cover 110 and may be fastened to the fastener coupling recess 156 of the body 150.

In the state in which the O-rings OR1, OR2, and OR3 to be evaluated are mounted in the O-ring mounting grooves 153-1, 153-2, and 153-3 of the body 150, the body 150 and the cover 110 may be coupled to each other by fastening of the coupling fastener 120.

As the result of the body 150 and the cover 110 being coupled to each other, a plasma gas penetration path configured to allow plasma gas to penetrate into the mounted O-rings OR1, OR2, and OR3 to be evaluated therethrough may be formed.

The plasma gas penetration path may include an inner penetration path and an outer penetration path.

Referring to FIG. 3, as the result of the body 150 and the cover 110 being coupled to each other, a gap D1 is formed between inner contact surfaces of the body 150 and the cover 110, and the gap D1 formed between the inner contact surfaces of the body 150 and the cover 110 may function as the inner penetration path, whereby plasma gas introduced through the cover interior penetration through-hole 111 can penetrate through the inner penetration path.

In addition, as the result of the body 150 and the cover 110 being coupled to each other, a gap DI is also formed between outer contact surfaces of the body 150 and the cover 110, and the gap D1 formed between the outer contact surfaces of the body 150 and the cover 110 may function as the outer penetration path, whereby plasma gas from the outside can penetrate through the outer penetration path.

The plasma gas that penetrates through the inner penetration path may come into contact with the O-ring OR1 to be evaluated, which is mounted in the inner penetration O-ring mounting groove 153-1, whereby the plasma resistance characteristics of the O-ring OR1 to be evaluated may be determined.

In addition, the plasma gas that penetrates through the outer penetration path may come into contact with the O-ring OR3 to be evaluated, which is mounted in the outer penetration O-ring mounting groove 153-3, whereby the plasma resistance characteristics of the O-ring OR3 to be evaluated may be determined.

Furthermore, some of the plasma gas that penetrates through the inner penetration path may continue to penetrate while the plasma gas is in contact with the O-ring OR1 to be evaluated, which is mounted in the inner penetration O-ring mounting groove 153-1, and the O-ring OR2 to be evaluated, which is mounted in the sealing O-ring mounting groove 153-2, may perform a sealing function to prevent further diffusion of the plasma gas that penetrates through the inner penetration path.

In addition, some of the plasma gas that penetrates through the outer penetration path may continue to penetrate while the plasma gas is in contact with the O-ring OR3 to be evaluated, which is mounted in the outer penetration O-ring mounting groove 153-3, and the O-ring OR2 to be evaluated, which is mounted in the sealing O-ring mounting groove 153-2, may perform a sealing function to prevent further diffusion of the plasma gas that penetrates through the outer penetration path.

That is, due to the sealing function of the O-ring OR2 to be evaluated, which is mounted in the sealing O-ring mounting groove 153-2, the plasma gas that penetrates through the inner penetration path can no longer diffuse in an outward direction, and furthermore, the plasma gas that penetrates through the outer penetration path can no longer diffuse in an inward direction.

This makes it possible to evaluate the plasma resistance characteristics of the O-ring OR1 to be evaluated, which is mounted in the inner penetration O-ring mounting groove 153-1, for inner penetration of the plasma gas and to evaluate the plasma resistance characteristics of the O-ring OR3 to be evaluated, which is mounted in the outer penetration O-ring mounting groove 153-3, for outer penetration of the plasma gas.

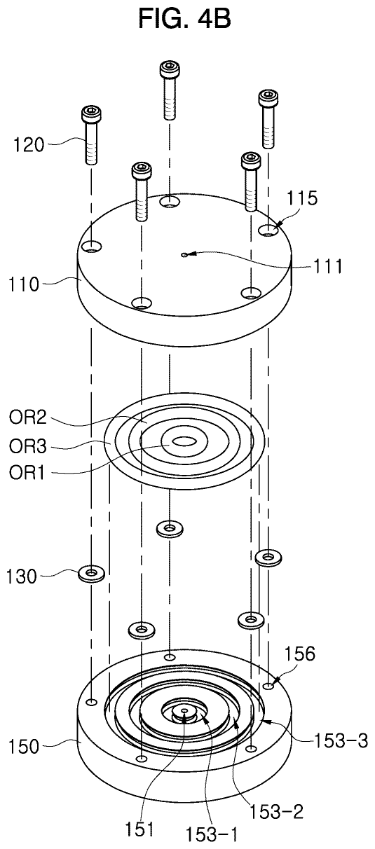

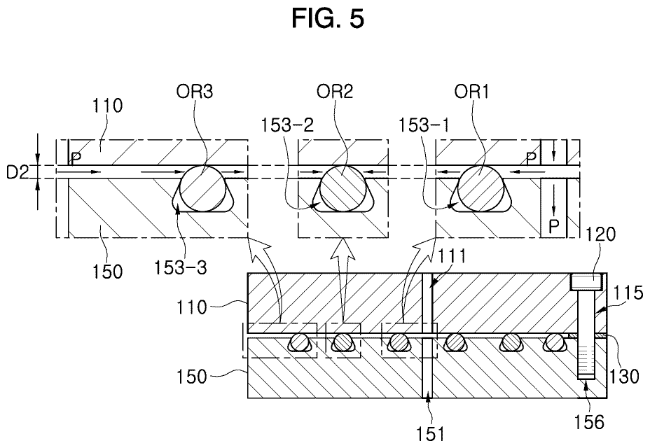

Furthermore, the plasma-resistant O-ring evaluation unit according to the present disclosure may adjust the penetration amount of plasma gas to evaluate the plasma resistance characteristics of the O-ring to be evaluated. In this regard, FIGS. 4A, 4B and 5 are views showing an embodiment of adjusting the gap of the plasma gas penetration path in the plasma-resistant O-ring evaluation unit according to the present disclosure.

In describing the present embodiment, a description of components identical or similar to the components of the embodiment of FIGS. 1A to 3 described above will be omitted or briefly given.

A gap adjustment ring 130 may be provided between the cover 110 and the body 150, and the gap adjustment ring 130 may be fixed to the coupling fastener 120 by fastening.

As the result of the gap adjustment ring 130 being disposed between the cover 110 and the body 150, as shown in FIG. 5, the gap between the inner contact surfaces of the body 150 and the cover 110 may be extended to D2, whereby the inner penetration path may be extended accordingly. In addition, the gap between the outer contact surfaces of the body 150 and the cover 110 may also be extended to D2, whereby the outer penetration path may be extended accordingly.

As the result of extending the inner penetration path, the inner penetration amount of the plasma gas may be increased, and as the result of extending the outer penetration path, the outer penetration amount of the plasma gas may be increased. Furthermore, the number of the gap adjustment rings 130 or the thickness of each of the gap adjustment rings 130 may be changed to adjust the gap between the inner contact surfaces and the gap between the outer contact surfaces, whereby the penetration amount of the plasma gas may be adjusted.

The plasma-resistant O-ring evaluation unit according to the present disclosure described above may be disposed in a plasma-resistant O-ring evaluation device to evaluate the plasma resistance characteristics of a plurality of various O-rings at one time.

A plasma-resistant O-ring evaluation device according to the present disclosure may include a chamber having an O-ring evaluation space configured to provide a plasma environment, a plasma-resistant O-ring evaluation unit disposed in the O-ring evaluation space, and a plasma environment creation unit configured to create the plasma environment in the O-ring evaluation space of the chamber.

The plasma environment creation unit may create the plasma environment in the O-ring evaluation space of the chamber in a CCP mode. Alternatively, the plasma environment creation unit may create the plasma environment in the O-ring evaluation space of the chamber in an ICP mode.

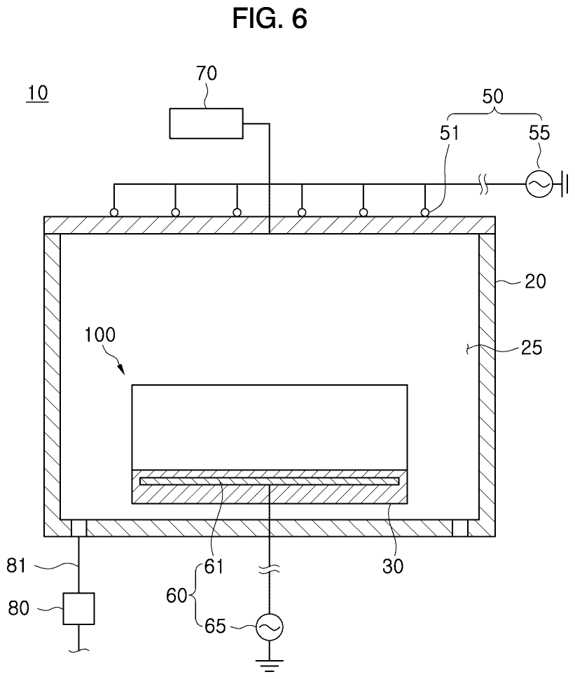

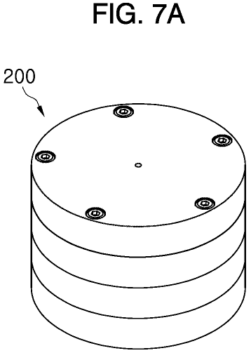

FIG. 6 is a view showing an embodiment of the plasma-resistant O-ring evaluation device according to the present disclosure.

A chamber 20 of the plasma-resistant O-ring evaluation device 10 has an O-ring evaluation space 25 defined therein, and the plasma-resistant O-ring evaluation unit 100 described above may be disposed in the O-ring evaluation space 25.

In one example, the plasma-resistant O-ring evaluation unit 100 may be seated on a support 30.

The plasma environment creation unit may include a gas supply means 70 configured to supply gas to the O-ring evaluation space 25 of the chamber 20 and an RF power supply means configured to create a plasma environment in the O-ring evaluation space 25 through arc discharge.

The RF power supply means may include an upper power supply means 50 and a lower power supply means 60. The upper power supply means 50 may include an antenna 51 and a power supply 55. The lower power supply means 60 may include an electrode 61 and a power supply 65.

Furthermore, an exhaust line 81 and an exhaust pump 80 configured to discharge gas from the chamber 20 may be provided.

The plasma-resistant O-ring evaluation device of FIG. 6 may be variously modified. In addition, the plasma-resistant O-ring evaluation device of FIG. 6 is described as being operated in an ICP mode; however, a CCP mode may be applied.

Consequently, it is possible to quickly and accurately evaluate the plasma resistance characteristics of various types of O-rings using the plasma-resistant O-ring evaluation device.

The plasma-resistant O-ring evaluation unit according to the present disclosure may be variously modified, and other embodiments of the plasma-resistant O-ring evaluation unit according to the present disclosure will hereinafter be described.

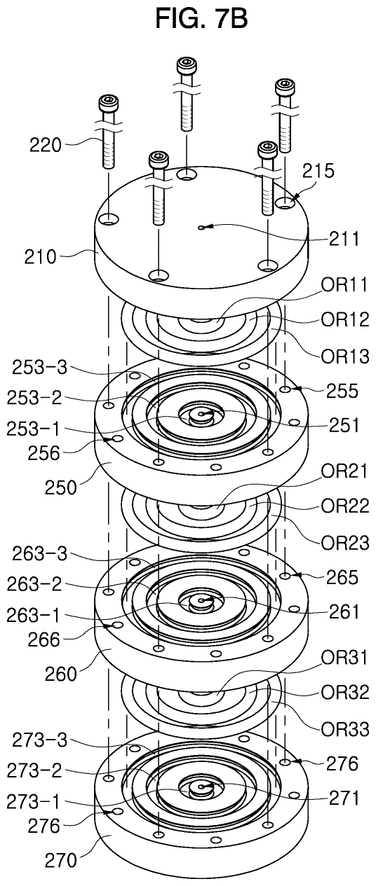

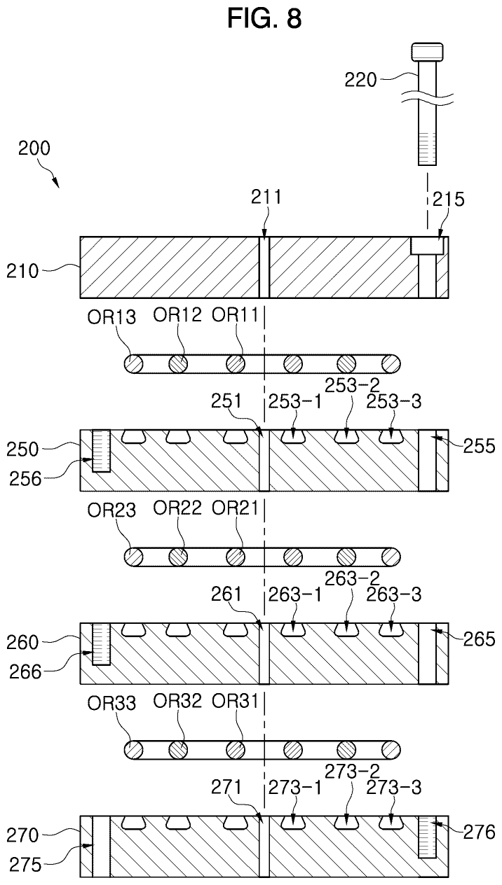

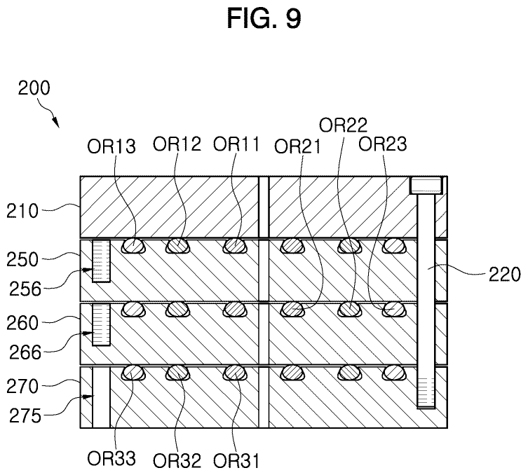

FIGS. 7A to 9 are views showing another embodiment of the plasma-resistant O-ring evaluation unit according to the present disclosure.

In describing the present embodiment, a description of components identical or similar to the components of the previous embodiment will be omitted or briefly given.

A plasma-resistant O-ring evaluation unit 200 may be configured such that a plurality of bodies 250, 260, and 270 is sequentially mounted to the bottom of a cover 210. For example, as shown in FIG. 7A and 5B, a first body 250, a second body 260, and a third body 270 may be sequentially mounted to the bottom of the cover 210.

In FIG. 7A and 7B, the three bodies, i.e., the first body 250, the second body 260, and the third body 270, are provided; however, two bodies may be provided four or more bodies may be provided depending on the circumstances.

The first body 250 may be an upper body, on the top of which the cover 210 is mounted, and the second body 260 may be a lower body, which is mounted to the bottom of the first body 250.

Each of the bodies 250, 260, and 270 may be provided with an O-ring mounting groove. In one example, inner penetration O-ring mounting grooves 253-1, 263-1, and 273-1 may be provided in central regions of the bodies 250, 260, and 270, respectively, sealing O-ring mounting grooves 253-2, 263-2, and 273-2 may be provided in middle regions of the bodies 250, 260, and 270, respectively, and outer penetration O-ring mounting grooves 253-3, 263-3, and 273-3 may be provided in outer regions of the bodies 250, 260, and 270, respectively.

Depending on the circumstances, the number and shape of O-ring mounting grooves formed in the bodies may be changed so as to be different from each other.

O-rings to be evaluated may be mounted in the O-ring mounting grooves of each of the bodies 250, 260, and 270.

In the state in which the O-rings to be evaluated are mounted in the O-ring mounting grooves of each of the bodies 250, 260, and 270, the cover 210 and the bodies 250, 260, and 270 may be sequentially coupled to each other.

The cover 210 may be provided with a fastener through-hole 215, and the bodies 250, 260, and 270 may also be provided with fastener through-holes 255, 265, and 275, respectively. In addition, the bodies 250, 260, and 270 may be provided with fastener coupling recesses 256, 266, and 276, respectively.

When the cover 210 and the bodies 250, 260, and 270 are coupled to each other, the first body 250 and the second body 260 may be located such that the fastener through-holes 255 and 265 of the first body 250 and the second body 260 are aligned with the fastener through-hole 215 of the cover 210, and the third body 270 may be located under the second body 260 such that the fastener coupling recess 276 of the third body 270 is aligned with the fastener through-holes 255 and 265 of the first body 250 and the second body 260.

In the state in which the cover 210, the first body 250, the second body 260, and the third body 270 are located as described above, a coupling fastener 220 may be sequentially inserted through the fastener through-hole 215 of the cover 210 and the fastener through-holes 255 and 265 of the first body 250 and the second body 260, and may be fastened to the fastener coupling recess 276 of the third body 270, whereby the cover 210, the first body 250, the second body 260, and the third body 270 may be coupled to each other.

When the cover 210, the first body 250, the second body 260, and the third body 270 are coupled to each other, a cover interior penetration through-hole 211 of the cover 210 and body interior penetration through-holes 251, 261, and 271 of the bodies 250, 260, and 270 may be connected to each other, thereby allowing inner penetration of plasma gas.

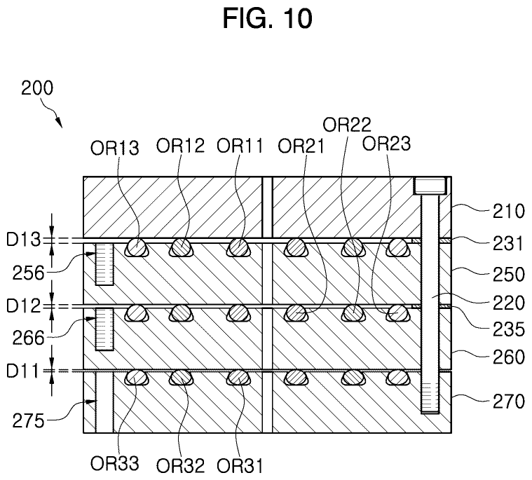

Furthermore, gaps between the contact surfaces of the cover 210, the first body 250, the second body 260, and the third body 270 may be adjusted differently. In this regard, FIG. 10 is a view showing another embodiment of adjusting the gap of the plasma gas penetration path in the plasma-resistant O-ring evaluation unit according to the present disclosure.

A first gap adjustment ring 231 may be mounted between the cover 210 and the first body 250 via the coupling fastener 220, and a second gap adjustment ring 235 may be mounted between the first body 250 and the second body 260 via the coupling fastener 220. No gap adjustment ring may be mounted between the second body 260 and the third body 270.

As shown in FIG. 10, the gap between the contact surfaces of the cover 210 and the first body 250 may be relatively greatly increased to D13 through the first gap adjustment ring 231, whereby the inner penetration path and the outer penetration path may be extended accordingly. As a result, the penetration amount of plasma gas may be greatly increased compared to the plasma gas penetration path between the second body 260 and the third body 270 having no gap adjustment ring therebetween.

In addition, the gap between the contact surfaces of the first body 250 and the second body 260 may be relatively slightly increased to D12 through the second gap adjustment ring 235 whereby the inner penetration path and the outer penetration path may be extended accordingly. As a result, the penetration amount of plasma gas may be slightly increased compared to the plasma gas penetration path between the second body 260 and the third body 270 having no gap adjustment ring therebetween.

The gap between the contact surfaces of the second body and the third body is D11, which means that the plasma gas penetration path is relatively narrow, whereby a smaller amount of plasma gas may penetrate accordingly.

As described above, it is possible to quickly and accurately evaluate the plasma resistance characteristics of the O-rings under various conditions by variously adjusting the penetration amount of plasma gas.

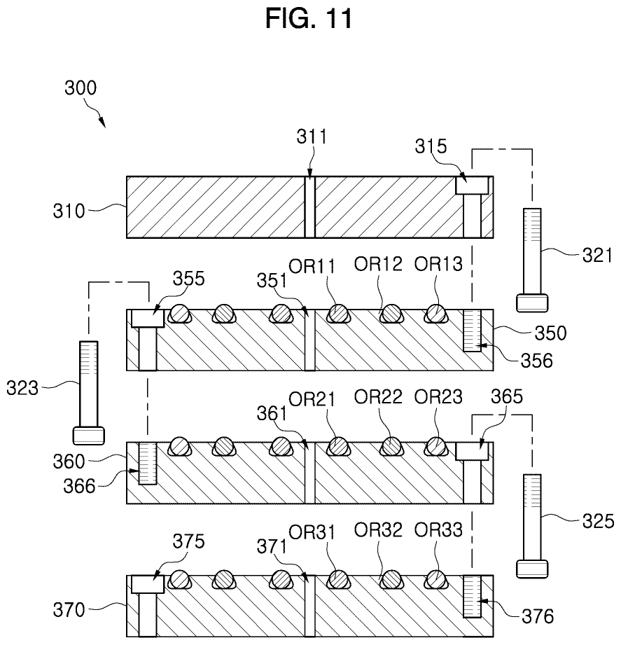

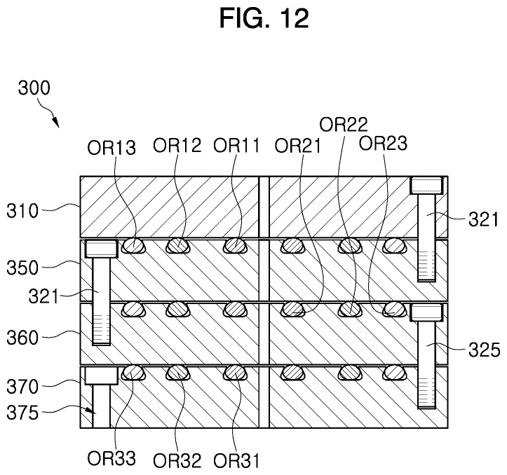

FIGS. 11 and 12 are views showing a further embodiment of the plasma-resistant O-ring evaluation unit according to the present disclosure.

In describing the present embodiment, a description of components identical or similar to the components of the embodiment of FIGS. 1A to 3 described above will be omitted or briefly given.

A plasma-resistant O-ring evaluation unit 300 may be configured such that a cover 310 and a plurality of bodies 350, 360, and 370 are coupled to each other.

The second body 360 and the third body 370 may be located such that a fastener coupling recess 376 of the third body 370 is aligned with a fastener through-hole 365 of the second body 360, and the second body 360 and the third body 370 may be coupled to each other using a third coupling fastener 325.

Next, the first body 350 and the second body 360 may be located such that a fastener coupling recess 366 of the second body 360 is aligned with a fastener through-hole 355 of the first body 350, and the first body 350 and the second body 360 may be coupled to each other using a second coupling fastener 323.

Finally, the cover 310 and the first body 350 may be located such that a fastener coupling recess 356 of the first body 350 is aligned with a fastener through-hole 315 of the cover 310, and the cover 310 and the first body 350 may be coupled to each other using a first coupling fastener 321.

As described above, the cover and the plurality of bodies may be coupled to each other in various ways to constitute a plasma-resistant O-ring evaluation unit.

As is apparent from the above description, according to the present disclosure, it is possible to quickly and accurately evaluate the plasma resistance characteristics of a plurality of various O-rings through a single plasma resistance evaluation process.

In addition, it is possible to simultaneously evaluate the plasma resistance characteristics of the O-ring for inner penetration of plasma gas and the plasma resistance characteristics of the O-ring for outer penetration of the plasma gas.

Furthermore, it is possible to evaluate the plasma resistance characteristics of the O-ring in various plasma environments by differently adjusting the penetration amount of plasma gas.

The effects of the present disclosure are not limited to the aforementioned effects, and other unmentioned effects will be clearly understood by a person having ordinary skill in the art to which the present disclosure pertains from the above description.

The above description is merely an exemplary description of the technical ideas of the present disclosure, and a person having ordinary skill in the art to which the present disclosure pertains will be able to make various modifications and variations without departing from the essential features of the present disclosure. Therefore, the embodiments of the present disclosure are intended to illustrate, not to limit, the technical ideas of the present disclosure, and the technical ideas of the present disclosure are not limited by the embodiments. The scope of protection of the present disclosure shall be construed in accordance with the following claims, and all technical ideas within the scope thereof shall be construed as falling within the scope of right of the present disclosure.

What is claimed is:

1. A plasma-resistant O-ring evaluation unit comprising:
a body provided in an upper surface thereof with an O-ring mounting groove corresponding in shape to an O-ring to be evaluated; and
a cover mounted to a top of the body, wherein
a plasma gas penetration path configured to allow plasma gas to penetrate into the mounted O-ring to be evaluated therethrough is formed by coupling between the body and the cover.

2. The plasma-resistant O-ring evaluation unit as claimed in claim 1,
wherein the cover is provided with a cover interior penetration through-hole configured to support inner penetration of the plasma gas, and
wherein the plasma gas penetration path comprises:
an inner penetration path formed by a gap between inner contact surfaces of the body and the cover by coupling between the body and the cover, the inner penetration path being configured to allow plasma gas introduced through the cover interior penetration through-hole to penetrate through the gap between the inner contact surfaces; and
an outer penetration path formed by a gap between outer contact surfaces of the body and the cover by coupling between the body and the cover, the outer penetration path being configured to allow the plasma gas from outside to penetrate through the gap between the outer contact surfaces.

3. The plasma-resistant O-ring evaluation unit as claimed in claim 2,
wherein the cover is provided in a center thereof with a cover interior penetration through-hole configured to support inner penetration of the plasma gas, and
wherein the body comprises:
an inner penetration O-ring mounting groove provided in a central region thereof;
a sealing O-ring mounting groove provided in a middle region thereof; and
an outer penetration O-ring mounting groove provided in an outer region thereof.

4. The plasma-resistant O-ring evaluation unit as claimed in claim 3,
wherein an O-ring mounted in the sealing O-ring mounting groove blocks a flow of the plasma gas penetrated through the inner penetration path and the outer penetration path.

5. The plasma-resistant O-ring evaluation unit as claimed in claim 2,
wherein the body is provided with a body interior penetration through-hole connected to the cover interior penetration through-hole.

6. The plasma-resistant O-ring evaluation unit as claimed in claim 2,
wherein the cover is provided with a fastener through-hole for coupling to the body,
wherein the body is provided with a fastener coupling recess corresponding to the fastener through-hole of the cover, and
wherein the plasma-resistant O-ring evaluation unit further comprises a coupling fastener inserted through the fastener through-hole of the cover and fastened to the fastener coupling recess of the body.

7. The plasma-resistant O-ring evaluation unit as claimed in claim 6, further comprising a gap adjustment ring fastened to the coupling fastener between the cover and the body.

8. The plasma-resistant O-ring evaluation unit as claimed in claim 7,
wherein the gap adjustment ring is changed in number to adjust the gap between the inner contact surfaces and the gap between the outer contact surfaces.

9. The plasma-resistant O-ring evaluation unit as claimed in claim 7,
wherein the gap adjustment ring is changed in thickness to adjust the gap between the inner contact surfaces and the gap between the outer contact surfaces.

10. The plasma-resistant O-ring evaluation unit as claimed in claim 3,
wherein the body comprises:
an upper body, to a top of which the cover is mounted; and
a lower body, to a top of which the upper body is mounted.

11. The plasma-resistant O-ring evaluation unit as claimed in claim 3,
wherein the body comprises a plurality of bodies sequentially mounted to a bottom of the cover.

12. The plasma-resistant O-ring evaluation unit as claimed in claim 10,
wherein the upper body is provided with a body interior penetration through-hole connected to the cover interior penetration through-hole.

13. The plasma-resistant O-ring evaluation unit as claimed in claim 10,
wherein each of the cover and the upper body is provided with a fastener through-hole,
wherein the lower body is provided with a fastener coupling recess corresponding to the fastener through-hole, and
wherein the plasma-resistant O-ring evaluation unit further comprises a coupling fastener inserted through the fastener through-hole and fastened to the fastener coupling recess.

14. The plasma-resistant O-ring evaluation unit as claimed in claim 13, further comprising a gap adjustment ring selectively fastened to the coupling fastener between the cover and the upper body or between the upper body and the lower body.

15. The plasma-resistant O-ring evaluation unit as claimed in claim 10,
wherein the cover is provided with a fastener through-hole for coupling to the upper body,
wherein the upper body is provided with a fastener coupling recess corresponding to the fastener through-hole of the cover and a fastener through-hole for coupling to the lower body, and
wherein the plasma-resistant O-ring evaluation unit further comprises a first coupling fastener inserted through the fastener through-hole of the cover and fastened to the fastener coupling recess of the upper body and a second coupling fastener inserted through the fastener through-hole of the upper body and fastened to a fastener coupling recess of the lower body.

16. The plasma-resistant O-ring evaluation unit as claimed in claim 15, further comprising a gap adjustment ring fastened to the first coupling fastener between the cover and the upper body or fastened to the second coupling fastener between the upper body and the lower body.

17. A plasma-resistant O-ring evaluation device comprising:
a chamber having an O-ring evaluation space configured to provide a plasma environment, wherein the plasma-resistant O-ring evaluation unit as claimed in claim 1 disposed in the O-ring evaluation space; and
a plasma environment creation unit configured to create the plasma environment in the O-ring evaluation space of the chamber.

18. The plasma-resistant O-ring evaluation device as claimed in claim 17,
wherein the plasma environment creation unit creates the plasma environment in the O-ring evaluation space of the chamber in a CCP mode.

19. The plasma-resistant O-ring evaluation device as claimed in claim 17,
wherein the plasma environment creation unit creates the plasma environment in the O-ring evaluation space of the chamber in an ICP mode.

20. A plasma-resistant O-ring evaluation device comprising:
a cover provided in a center thereof with a cover interior penetration through-hole configured to support inner penetration of plasma gas, the cover being mounted to a top of a body;
a plurality of bodies sequentially mounted to a bottom of the cover, each of the bodies being provided with a body interior penetration through-hole connected to the cover interior penetration through-hole, each of the bodies comprising an inner penetration O-ring mounting groove provided in a central region of an upper surface thereof, a sealing O-ring mounting groove provided in a middle region of the upper surface thereof, and an outer penetration O-ring mounting groove provided in an outer region of the upper surface thereof so as to correspond in shape to different O-rings to be evaluated;
a plasma-resistant O-ring evaluation unit comprising a plasma gas penetration path,
the plasma gas penetration path comprising an inner penetration path formed by a gap between inner contact surfaces of the body and the cover and between inner contact surfaces of the bodies by coupling between the body and the cover and coupling between the covers, the inner penetration path being configured to allow the plasma gas introduced through the cover interior penetration through-hole or the body interior penetration through-hole to penetrate through the gap between the inner contact surfaces, and an outer penetration path formed by a gap between outer contact surfaces of the body and the cover and between outer contact surfaces of the bodies, the outer penetration path being configured to allow the plasma gas from outside to penetrate through the gap between the outer contact surfaces;
a chamber having an O-ring evaluation space configured to provide a plasma environment, the plasma-resistant O-ring evaluation unit being disposed in the O-ring evaluation space; and
a plasma environment creation unit configured to create the plasma environment in the O-ring evaluation space of the chamber.
